(19) United States
(12) Patent Application Publication
(10) Pub. No.: US 2025/0183654 A1
(43) Pub. Date: Jun. 5, 2025

(54) METHOD AND APPARATUS FOR PROTECTING RECEIVER CIRCUITRY FROM LARGE SUDDEN INTERFERENCE SIGNALS

(71) Applicant: Intel Corporation, Santa Clara, CA (US)

(72) Inventors: David GRAHAM, Gilbert, AZ (US); Peter PAWLIUK, Tempe, AZ (US)

(21) Appl. No.: 18/527,443

(22) Filed: Dec. 4, 2023

(51) Int. Cl. H02H 7/20; H03F 3/19; H04B 1/10

(52) U.S. Cl. CPC H02H 7/20; H03F 3/19; H04B 1/10; H03F 2200/294; H03F 2200/451

(57) ABSTRACT

A method and apparatus for protecting receiver circuitry from damage from interference signals. The apparatus includes a digital step attenuator (DSA) configured to attenuate a received signal, an over-voltage detector configured to detect a peak of the received signal at an input of receiver circuitry and activate an over-voltage detection signal if the peak of the received signal exceeds a detection threshold, and a digital control block configured to send a control code to the DSA to control an attenuation step of the DSA. The digital control block sends a control code to set the attenuation step of the DSA at a pre-configured attenuation step in response to the over-voltage detection signal asserted by the over-voltage detector. The pre-configured attenuation step is set to a level that can protect the receiver circuitry from the interference signals.

### BACKGROUND

Modern base station receivers include front-end radio frequency (RF) components and back-end transceiver integrated circuits (ICs) that are normally designed in advanced complementary metal-oxide-semiconductor (CMOS) process nodes. The very small devices used in these advanced process nodes are vulnerable to damage from signals with large voltage swings. Large voltage swings on these small devices can cause physical damage to the integrated circuits. Base station receivers can be subjected to sudden, high-power blocking or interference signals. These blocking or interference signals can cause damages to the unprotected receiver (RX) circuitries in a transceiver. These large, sudden signals can cause damages much quicker than traditional automatic gain control (AGC) systems can respond (typically few micro-seconds). Thus, traditional AGC systems cannot be relied upon to protect the sensitive transceivers from these large, rapidly occurring interfering signals. While an RF sensor and a clamping mechanism can be used to protect the sensitive transceiver RX path from damage, a good solution is still needed for releasing the clamping mechanism to resume normal receiver operations once the strong blocking condition goes away.

Conventionally, diode clamps have been used for the protection from the sudden high-power signals. Back-to-back diodes can be used to prevent voltage swings from exceeding a signal level set by the diode junction voltage. Higher voltages can be achieved by stacking diodes in series. The disadvantage of this solution is that a forward-biased diode is quite non-linear. Modern base station receivers require very high linearity and can be intolerant of the non-linearity of the diode clamps. The diodes also add capacitance on the signal path that can limit the frequency range of the receiver circuitry.

Alternatively, a signal detector has been used with an RF clamp and a timer. A peak-voltage detector can be used to detect large signals that exceed safe operating regions of the device. When a signal level is detected to be exceeding the pre-determined threshold, a clamping mechanism is actuated to limit the signal imposed on the transceiver RX signal path. However, following clamping, the peak detector can no longer accurately detect the signal levels either due to change in the node impedance or due to the clamping (especially if the peak detector is after the clamping mechanism). Thus, a timer is used to release the clamping mechanism with the assumption that the strong interfering signal will have a finite duration. However, since the interfering signal dynamics are not known, the timer-based release of the clamping mechanism can result in a cyclic clamp-release behavior that can be disruptive to signal reception and can unnecessarily expose the receiver to multiple short bursts of the strong blocking signal.

Alternatively, transceiver circuitry can be designed on less aggressive process nodes that are more robust to large signal swings without damage to the circuits. However, these process nodes are not conducive to meet requirements for very high scale integration of complex analog and digital circuits for competitive transceiver ICs. Transistor speeds in these process nodes do not allow for use of high-speed circuits required for modern cellular base station transceivers. One possible work-around for this issue can be to co-package RF circuitry fabricated on a more robust process node with digital content fabricated in a higher density, leading edge process technology. However, this adds logistic overhead for manufacturing, testing, and packaging of the devices.

### BRIEF DESCRIPTION OF THE FIGURES

Some examples of apparatuses and/or methods will be described in the following by way of example only, and with reference to the accompanying figures, in which

FIG. 1 shows an example conventional receiver including an automatic gain control (AGC) system;

FIG. 2 is a block diagram of an example receiver including rapid attenuation for protecting the receiver circuitry from large sudden interference signals;

FIG. 3 is an example sample timing diagram of control system transitions;

FIG. 4 is a block diagram of an example receiver including rapid attenuation for protecting the receiver circuitry from large sudden interference signals;

FIG. 5 is a flow diagram of a method for rapid attenuation for protecting receiver circuitry from interference signals;

FIG. 6 shows an example apparatus for protecting receiver circuitry from interference signals;

FIG. 7 illustrates a user device in which the examples disclosed herein may be implemented; and

FIG. 8 illustrates a base station or infrastructure equipment radio head in which the examples disclosed herein may be implemented.

### DETAILED DESCRIPTION

Various examples will now be described more fully with reference to the accompanying drawings in which some examples are illustrated. In the figures, the thicknesses of lines, layers and/or regions may be exaggerated for clarity.

Accordingly, while further examples are capable of various modifications and alternative forms, some particular examples thereof are shown in the figures and will subsequently be described in detail. However, this detailed description does not limit further examples to the particular forms described. Further examples may cover all modifications, equivalents, and alternatives falling within the scope of the disclosure. Like numbers refer to like or similar elements throughout the description of the figures, which may be implemented identically or in modified form when compared to one another while providing for the same or a similar functionality.

It will be understood that when an element is referred to as being “connected” or “coupled” to another element, the elements may be directly connected or coupled or via one or more intervening elements. If two elements A and B are combined using an “or”, this is to be understood to disclose all possible combinations, i.e. only A, only B as well as A and B. An alternative wording for the same combinations is “at least one of A and B”. The same applies for combinations of more than 2 elements.

The terminology used herein for the purpose of describing particular examples is not intended to be limiting for further examples. Whenever a singular form such as “a,” “an” and “the” is used and using only a single element is neither explicitly or implicitly defined as being mandatory, further examples may also use plural elements to implement the same functionality. Likewise, when a functionality is subsequently described as being implemented using multiple elements, further examples may implement the same functionality using a single element or processing entity. It will be further understood that the terms “comprises,” “comprising,” “includes” and/or “including,” when used, specify the presence of the stated features, integers, steps, operations, processes, acts, elements and/or components, but do not preclude the presence or addition of one or more other features, integers, steps, operations, processes, acts, elements, components and/or any group thereof.

Unless otherwise defined, all terms (including technical and scientific terms) are used herein in their ordinary meaning of the art to which the examples belong.

Examples will be disclosed herein demonstrating a temporary override of the AGC system in response to a sudden strong interference signal (a blocker signal) to protect the receiver (RX) circuitry from damage. The system then allows for smooth transition back to the system AGC loop. The example mechanisms disclosed herein allow for quick activation of protection for sensitive RX circuitry and smooth exit of the protection state to minimize performance impact to the receiver system. The example schemes disclosed herein utilize a fast-reacting over-voltage signal detector (a magnitude/power detector), a small logic control block, and a step attenuation block to quickly respond to exposure from rapid, large signals at the transceiver RX input by autonomously and asynchronously engaging a large attenuation step, and then hand over the control of the step attenuation to the AGC system after the AGC system has had a sufficient time to adjust the requested attenuation to match the interfering signal level thus seamlessly recovering from the large step.

This scheme provides a robust and autonomous solution to assure reliability of the transceiver circuitry even in the presence of sudden, strong blocker signals. This solution allows for transceiver circuitry to be monolithically designed on more aggressive process nodes that are more conducive to high levels of integration, but that are less robust to strong analog/RF signals, thus enabling a potentially more cost effective and power efficient solution.

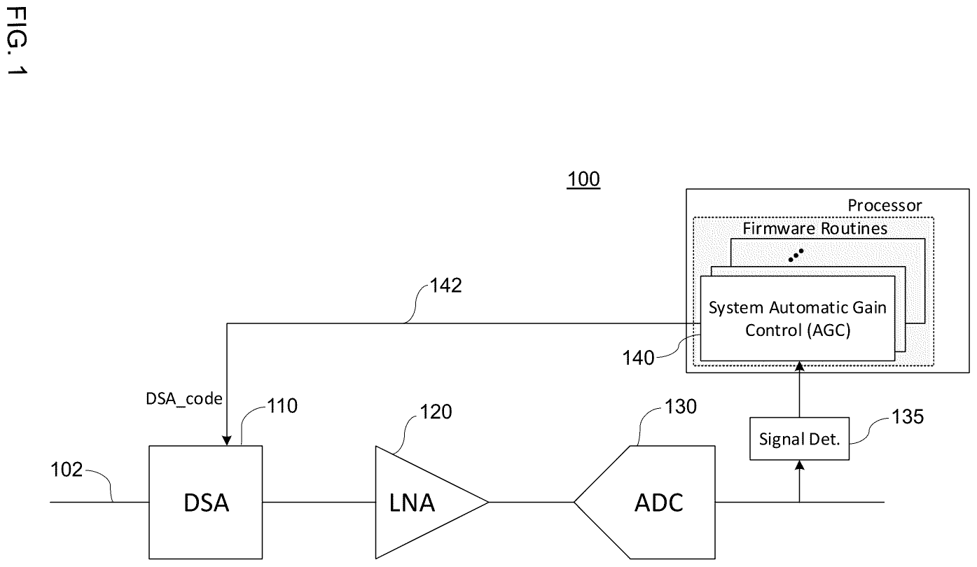

FIG. 1 shows an example conventional receiver 100 including an automatic gain control (AGC) system. The receiver 100 may be included in a base station transceiver IC as an example. The receiver 100 may include a digital step attenuator (DSA) 110 (i.e., a digitally-controlled analog step attenuator), a low noise amplifier (LNA) 120, an analog-to-digital converter (ADC) 130, and an AGC controller 140. The receiver 100 may also include a buffer amplifier (not shown) before and/or after the LNA 120.

A received signal 102 may be attenuated by the DSA 110. A DSA is a device that is used to apply a controlled amount of attenuation to the received signal. The amount of attenuation is digitally controlled, usually in binary steps. Unlike continuously variable attenuators, a DSA switches in discrete, finite attenuation states to achieve different attenuation states.

After being attenuated by the DSA 110, or going through the DSA 110 without attenuation, the received signal is amplified by the LNA 120 and then converted to digital data by the ADC 130. The signal level of the received signal is controlled by the AGC control loop. The signal level of the received signal is detected by the signal detector 135 in the digital domain based on the output of the ADC 130 and the AGC controller 140 sends a DSA control code 142 to the DSA 110 based on the detected signal level to adjust the level of the received signal at the proper level in analog domain.

In normal AGC operations, the DSA 110 is used to properly adjust the signal level presented to the LNA 120 and the ADC 130 such that the ADC 130 can operate within its allowable signal range. An ADC has a usable dynamic range bounded by its noise floor and its maximum or full-scale (FS) input. The ADC will have a linear operating region within which distortion products due to circuit non-linearities are sufficiently low so as not to impede specified ADC performance. The AGC system is designed to assure that the ADC input signal resides within the linear operating range of the ADC. The AGC system typically involves a signal level threshold (AGC threshold) above which attenuation would be engaged to reduce the signal swing at the input of the ADC 130. If AGC attenuation has been applied in the system, there is also a signal threshold for detecting when to remove the attenuation from the system to allow the desired signals to be presented to the ADC 130 at a more optimal signal level. The AGC system works to maintain the signal level at the ADC input within the pre-defined upper and lower thresholds.

Control loops for the RX AGC systems (e.g., in a base station) have reaction and settling time requirements set by system parameters. However, the AGC system is typically too slow to prevent damage to the sensitive ICs when presented with sudden large blocker signals. The DSA 110 is typically designed using passive structures that can be designed to be robust to very large signal swings. In contrast, active circuits, such as the LNA or buffer amplifier, are typically more susceptible to damage from large signal swings and need to be protected from the large signal swings to avoid physical damage to the circuitry.

Base station receivers can be exposed to sudden, extremely strong signals that can have sufficient signal power to potentially damage sensitive receiver circuitry, such as an LNA, if the receiver is configured to operate at or near full gain conditions. These strong interfering signals (e.g., blocker signals) can appear quickly and can result in damage to the circuitry prior to the normal AGC loop's ability to respond and adjust the DSA based on the strong signal.

The example schemes disclosed herein introduce a mechanism to prevent circuit damage by quickly responding to sudden interfering signals (e.g., a blocker signal) by autonomously adding attenuation in the signal path without contending with the AGC control loop.

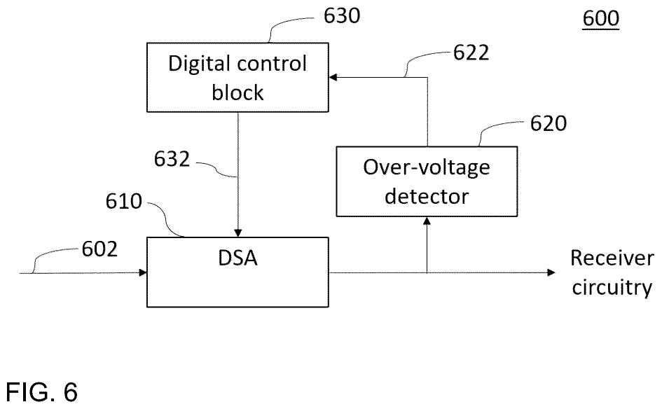

FIG. 6 shows an example apparatus 600 for protecting receiver circuitry from interference signals. The apparatus 600 may be included in a receiver, e.g., a base station receiver. The apparatus 600 includes a DSA 610, an over-voltage detector 620, and a digital control block 630. The apparatus 600 receives a signal 602. The received signal 602 may be an RF signal. The DSA 610 is configured to attenuate the received signal 602. The attenuation of the DSA 610 is controlled by the DSA code set by the digital control block 630. The DSA 610 is included in the receive chain to attenuate the received signal 602 to a proper level so as not to overload the receiver circuitries on the receive chain. The received signal 602, after being attenuated by the DSA 610, or going through the DSA 610 without attenuation, is forwarded to the downstream receiver circuitry (e.g., LNA, ADC, etc.).

The over-voltage detector 620 is placed at the input of the receiver circuitry. The over-voltage detector 620 is configured to detect an over-voltage condition on the received signal at an input of receiver circuitry. The over-voltage detector 620 may detect the magnitude of power of the received signal at the input of the receiver circuitry and activates an over-voltage detection signal 622 if the peak (e.g., magnitude or power) of the received signal at the input of the receiver circuitry exceeds a detection threshold. The detection threshold may be set several dB lower than a maximum allowable signal power that can cause damage to the receiver circuitry.

The digital control block 630 is configured to send a control code 632 to the DSA 610 to control the attenuation step of the DSA 610. In response to the over-voltage detection signal 622 asserted by the over-voltage detector 620, the digital control block 630 immediately sends a control code 632 to the DSA 610 to set the attenuation step of the DSA 610 at a pre-configured attenuation step. The pre-configured attenuation step may be selected/configured to assure that the receiver circuitry operates without damage for any signal level up to a maximum specified level for the receiver circuitry. The pre-configured attenuation step of the DSA 610 may be set to a level that can protect the receiver circuitry from the interference signals (blocker signals). By setting the attenuation of the DSA 610 to the pre-configured step, a received signal exceeding the detection threshold is immediately attenuated below the pre-configured level for the protection of the receiver circuitry.

The receiver may implement an automatic gain control for controlling the gain of the received signal. The AGC controller in the receiver may be configured to send a DSA step setting to the digital control block 630 to control the attenuation step of the DSA 610 based on the level of the received signal detected at an output of the receiver circuitry. The digital control block 630 may be configured to maintain the pre-configured attenuation step until a DSA step setting requested by the AGC controller exceeds the pre-configured attenuation step.

The digital control block 630 may also be configured to activate an over-threshold signal to the AGC controller if the over-voltage detection signal 622 is activated by the over-voltage detector 620 and maintain the over-threshold signal until the DSA step setting requested by the AGC controller exceeds the pre-configured attenuation step. The AGC controller may then use a pre-configured step for AGC control while the over-threshold signal is being asserted. Upon request for attenuation exceeding the pre-configured attenuation step by the AGC controller, the digital control block 630 deactivates the over-threshold signal and the AGC controller takes the control back.

An over-voltage signal detector is placed at the vulnerable node in the signal path. When a peak signal exceeds a pre-determined threshold at the vulnerable node in the signal path, the AGC control system is temporarily bypassed and a fixed attenuation step (with sufficient attenuation to prevent circuit damage) is rapidly added to the signal path. In other words, an over-voltage control temporarily overrides the AGC system by adding a fixed attenuation step to the signal path. An over-threshold condition is then signaled to the AGC system which will result in requesting for additional AGC attenuation. A digital control block monitors the amount of attenuation requested by the AGC control loop and maintains the fixed attenuation step until the attenuation requested by the AGC control loop exceeds the fixed attenuation step, at which point the over-threshold signal is cleared and the system AGC resumes full control of the requested system gain.

In some modern process nodes, an LNA input node can tolerate signal swings comparable to the specified maximum circuit supply rail without sustaining damage. For example, in some modern process nodes a signal level of about 1.4 Vpk (approximately +10 dBm in a 100 Ohm system) can be allowed without sustaining damage. The peak detection threshold can be set several dB lower than the maximum allowable signal power to assure a margin to the level that can cause damage. For example, a detection threshold of +5 dBm at the LNA input may be used. Regarding the step size of the DSA, if the system requirement dictates supporting an input signal of up to +15 dBm without damage with the receiver operating at full gain, then a bare minimum of 5 dB of DSA attenuation would be required to protect the LNA, and preferably some safety margin would be desired. For example, a step size of 10 dB may be used.

The typical AGC threshold of the system will be much lower than the LNA circuit damage threshold. Signal levels exceeding the AGC threshold will cause the ADC to overload, thus blocking proper signal reception. Consider a receiver system with 10 dB of gain between the receiver input and ADC input and with an ADC having a defined full-scale input of 0 dBm. In the example using an LNA protection threshold of +5 dBm at the LNA input, this would correspond to a signal level 15 dB above the allowable full-scale input of the ADC, hence the sudden presence of the strong blocker would completely overload the ADC and corrupt signal integrity until the AGC loop can properly adjust to account for the signal level. The example schemes disclosed herein will quickly and autonomously respond to the sudden strong signal to protect the circuitry from damage, and then allow for a smooth transition back to the system AGC loop.

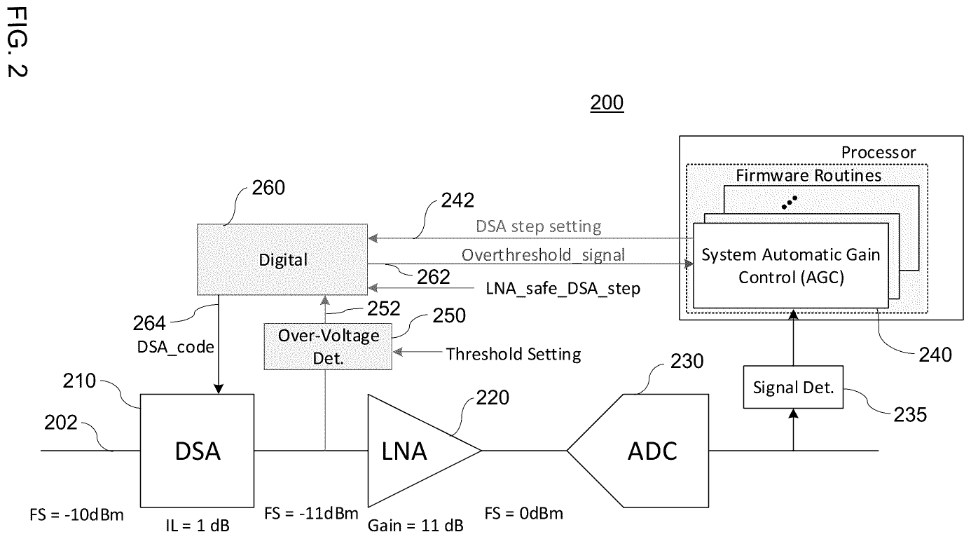

FIG. 2 is a block diagram of an example receiver 200 including overload protection gain control for protecting the receiver circuitry from large sudden interference signals. The receiver 200 may be integrated in a receiver chain of a transceiver IC (e.g., a base station transceiver). The receiver 200 may include a DSA 210 (i.e., a digitally controlled analog step attenuator), an LNA 220, an ADC 230, an AGC controller 240, an over-voltage detector 250, and a digital control block 260. The receiver 200 may also include a buffer amplifier (not shown) before and/or after the LNA 220, etc.

A received signal 202 may be attenuated by the DSA 210. The DSA 210 is a device used to apply a controlled amount of attenuation to the received signal 202. The amount of attenuation is digitally controlled, e.g., in binary steps. The received signal after being attenuated by the DSA 210, or going through the DSA 210 without attenuation, is amplified by the LNA 220 and then converted to digital by the ADC 230. The signal level of the received signal is detected by the signal detector 235 in the digital domain based on the output of the ADC 230 and the AGC controller 240 may send a DSA step setting 242 to the digital control block 260 based on the signal level at the output of the ADC 230 to adjust the level of the received signal. The AGC controller 240 may be a firmware routine running on a processor. The AGC loop shown in FIG. 2 is merely an example and may be implemented differently (e.g., the AGC loop may be implemented based on the signal level detected at the input of the ADC, etc.).

For the sake of explanation, example signal levels and circuit parameters are included in FIG. 2. However, it should be noted that the signal levels and circuit parameters shown in FIG. 2 are merely an example and different values/parameters may be used. In this example, a signal level of 0 dBm at the input of the ADC 230 represents the full-scale input of the ADC 230. The LNA 220 may have a gain of 11 dB and the DSA 210 may have an insertion loss of 1 dB. Therefore, a signal level of-10 dBm at the DSA input corresponds to a full-scale signal at the ADC input. The AGC threshold is set lower than the full-scale input at the ADC input to assure that signal peaks due to modulation and signal fading, etc. do not exceed the ADC full-scale.

Base station manufacturers require receiver circuitries in the transceiver IC to tolerate blocker signal levels up to a certain signal level (e.g., +15 dBm or higher) at the transceiver IC receiver (RX) input pins. The DSA is designed to withstand the high signal level without damage and can provide sufficient attenuation to assure that the LNA and the ADC can still operate at or below the defined full-scale. However, if a blocker signal suddenly appears when the DSA has little or no attenuation engaged, the LNA or other vulnerable circuitry in the receive chain is left exposed to dangerously high signal levels that can damage the circuit.

In order to protect the RX circuitries from the sudden strong interference signals, in examples, a fast over-voltage detector 250 (e.g., a power or voltage detector) is placed at an input of the circuit to be protected (e.g., the input node of the LNA, buffer, etc.). A magnitude or power of the received signal at the input of the circuit to be protected is detected by the over-voltage detector 250. For example, the over-voltage detector 250 may convert an RF input signal into an output DC voltage proportional to the RF input power or magnitude. The over-voltage detector 250 is configured with a pre-configured threshold (a detection threshold). The over-voltage detector 250 detects the peak level of the received signal at the input of the LNA 220 (or a buffer, etc.) and asserts an over-voltage detection signal 252 to the digital control block 250 if the peak of the received signal exceeds the detection threshold. For example, the over-voltage detector 250 may activate the over-voltage detection signal 252 if the magnitude or square of the instantaneous RF input voltage exceeds the detection threshold. The detection threshold may be set several dB lower than the signal level that can result in a damage to the circuit (e.g., the LNA circuit, etc.). When a signal level is detected greater than this detection threshold, the system will asynchronously and immediately force the DSA 210 to a pre-configured amount of attenuation (independent of the DSA step setting provided by the system AGC 240) to assure that the circuit (e.g., the LNA, etc.) is protected from damage.

The digital control block 260 controls the DSA based on the over-voltage detection signal 252 from the over-voltage detector 250 and a DSA step setting 242 from the AGC controller 240. Inputs into the digital control block 260 include the output from the over-voltage detector 250 (i.e., the over-voltage detection signal 252), the DSA step setting 242 from the AGC controller 240, and a pre-configured DSA step setting (e.g., LNA_safe_DSA_step) to set the amount of DSA step in the event of detection of a potentially harmful signal level (i.e., when the over-voltage detection signal 252 is activated). Outputs from the digital control block 260 include an over-threshold indication signal 262 to communicate that an over-threshold condition has occurred, and a DSA control code 264 (DSA_code) to the DSA 210 to set the DSA attenuation level. The range of the DSA control code 264 is from 0 to the maximum code that maps to a DSA value from the maximum attenuation value to 0 dB with a certain step size. The over-threshold indication signal 262 indicates to the AGC controller 240 the requirement for additional AGC attenuation.

When the magnitude or power of the received signal exceeds the over-voltage detection threshold, the over-voltage detector 250 activates the over-voltage detection signal 252 to the digital control block 260. The digital control block 260 then immediately sets the DSA attenuation to the pre-configured DSA step value (LNA_safe_DSA_step) and actuates the over-threshold indication signal 262 (Overthreshold_signal) to the AGC controller 240. The pre-configured DSA step value (LNA_safe_DSA_step value) is selected to assure that the LNA (or any other sensitive receiver circuitry) will operate without damage with that amount of DSA attenuation for any signal level up to the maximum specified level (e.g., +15 dBm).

The digital control block 260 may include simple combinatorial logic and latches that are configured to perform the functions of generating the Overthreshold_signal, and forcing the DSA_code to be at the LNA_safe_DSA_step when the over-voltage detector 250 signals an over-voltage condition, and return the DSA step value to the DSA step setting from the AGC controller 240 once the conditions are met that there is no longer an over-voltage condition and that the requested DSA step is larger than the LNA_safe_DSA_step. The digital control block 260 may be implemented as hardware logic in order to respond quick enough to protect the sensitive circuitry. The AGC controller 240 may be implemented as a software control system or as a hardware state machine. In either case the AGC controller 240 would not be able to respond quick enough to perform the functions of the digital control block 260 due to latencies in the AGC controller 240.

The AGC controller 240 detects the over-threshold indication signal 262 and may send a request (i.e., a DSA step setting 242) to the digital control block 260 to increment DSA attenuation. The digital control block 260 will maintain the DSA attenuation set by the pre-configured DSA step value (LNA_safe_DSA_step) and will continue to hold the Overthreshold_signal high until the AGC controller 240 requests a DSA step setting greater than the pre-configured DSA step value (LNA_safe_DSA_step) and the over-voltage detector output has cleared, indicating that no potentially damaging signal is still present. At this point the AGC controller 240 is completely back in control of the DSA attenuator value and can adjust the system gain as needed for the given signal conditions. While the over-voltage protection DSA step is not properly timed to signal symbol intervals, this DSA step would only occur when potentially damaging signal levels are imposed on the receiver, in which case the desired signals will be blocked anyway due to the blocker overloading the receiver path. The example schemes disclosed herein override system AGC control and quickly apply attenuation to prevent damage to the receiver circuitry and then provide a method for naturally transitioning gain control back to the system AGC control loop.

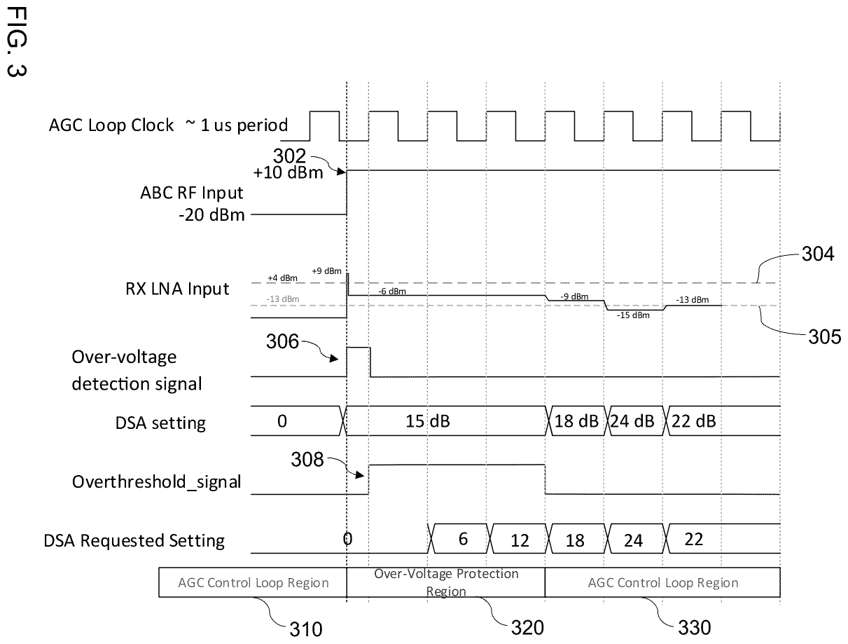

FIG. 3 is an example sample timing diagram of control system transitions. FIG. 3 shows a transition of DSA control from the system AGC loop to over-voltage protection operation and back to the system AGC loop. In this example, a +10 dBm RF input signal 302 is suddenly imposed on the receiver while no AGC attenuation is engaged by the system AGC control loop in a period 310. The over-voltage detector 250 detects that the received signal level exceeds the detection threshold 304 (+4 dBm in the example) and activates the over-voltage detection signal 306. In response to the over-voltage detection signal 306, the digital control block 260 sets the attenuation step of the DSA 210 to the pre-configured level (15 dB in this example). The received signal level at the LNA input is then immediately decreased. The digital control block 210 also activates the over-threshold indication signal 308 to the AGC controller 240. During this period 320 (over-voltage protection region), the digital control block 210 maintains the DSA attenuation level to the pre-configured level (15 dB in this example) until the DSA setting requested by the AGC control loop becomes greater than the pre-configured level. In this example, during this over-voltage protection region 320, the system AGC control loop uses 6 dB steps when signaled that an overload condition has occurred. As the DSA setting requested by the AGC controller 240 becomes greater than the pre-configured attenuation level (in this example, when the DSA setting requested by the AGC controller becomes 18 dB based on the desired AGC threshold 305 (−13 dBm in this example)), the digital control block 260 sets the DSA setting as requested by the system AGC control loop and deactivates the over-threshold signal 308. In the period 330, the system is then controlled by the AGC control loop again and, in this example with the desired AGC threshold set at-13 dBm at the RX LNA input, the system AGC continues to make gain adjustments until reaching the desired threshold 305.

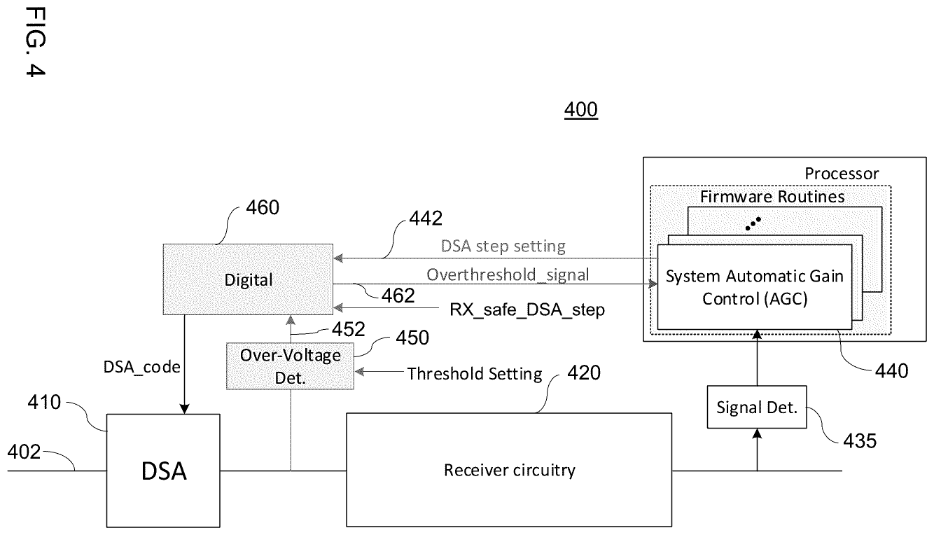

FIG. 2 illustrates a scheme for protection of the LNA and ADC from the sudden large interference signal. However, the scheme disclosed herein is not limited to the protection of LNA and ADC but can be extended for protection of any sensitive circuitry in the receiver. FIG. 4 is a block diagram of an example receiver 400 including over-voltage gain control for protecting the receiver circuitry from large sudden interference signals (blocker signal). The receiver 400 may be integrated in a receiver chain of a transceiver IC (e.g., a base station transceiver).

The receiver 400 may include a DSA 410, a receiver circuitry 420, an AGC controller 440, an over-voltage detector 450, and a digital control block 460. A received signal 402 may be attenuated by the DSA 410. The received signal after being attenuated by the DSA 410, or going through the DSA 410 without attenuation, is processed by the receiver circuitry 420. The receiver 400 implements an automatic gain control (AGC) of the received signal such that the level of the received signal is maintained at the proper level. Based on the signal level of the received signal detected by the signal detector 435 in a digital domain, the AGC controller 440 may send a DSA step setting 442 to the digital control block 460 to adjust the level of the received signal via the DSA 410.

The over-voltage detector 450 (e.g., a power or magnitude detector) is placed at an input of the receiver circuitry 420. A magnitude or power of the received signal at the input of the receiver circuitry 420 is detected by the over-voltage detector 450. The over-voltage detector 450 is configured with a pre-configured threshold (a detection threshold). If the peak level of the received signal at the input of the receiver circuitry 420 exceeds the detection threshold, the over-voltage detector 450 asserts an over-voltage detection signal 452 to the digital control block 450. The detection threshold may be set several dB lower than the signal level that can result in a damage to the receiver circuitry 420.

In response to the over-voltage detection signal 452, the digital control block 460 then immediately sets the DSA attenuation to the pre-configured DSA step value (RX_safe_DSA_step) and actuates the over-threshold indication signal 462 (Overthreshold_signal) to the AGC controller 440. The pre-configured DSA step value (RX_safe_DSA_step value) is selected to assure that the receiver circuitry 420 will operate without damage with that amount of DSA attenuation for any signal level up to the maximum specified level.

The AGC controller 440 detects the over-threshold indication signal 462 and may send a request (i.e., a DSA step setting 442) to the digital control block 460 to increment DSA attenuation. The digital control block 460 will maintain the DSA attenuation set by the pre-configured DSA step value (RX_safe_DSA_step) and will continue to hold the Overthreshold_signal 462 high until the AGC controller 440 requests a DSA step value greater than the pre-configured DSA step value (RX_safe_DSA_step). At this point the Overthreshold_signal 462 is released and the AGC controller 440 is completely back in control of the DSA attenuator value and can adjust the system gain as needed for the given signal conditions. While the over-voltage protection DSA step is not properly timed to signal symbol intervals, this DSA step would only occur when potentially damaging signal levels are imposed on the receiver, in which case the desired signals will be blocked anyway due to the blocker overloading the receiver path. The example schemes disclosed herein override the system AGC and quickly apply sufficient attenuation in the signal path to prevent damage to the receiver circuitry and then provide a method for naturally transitioning gain control back to the system AGC control loop.

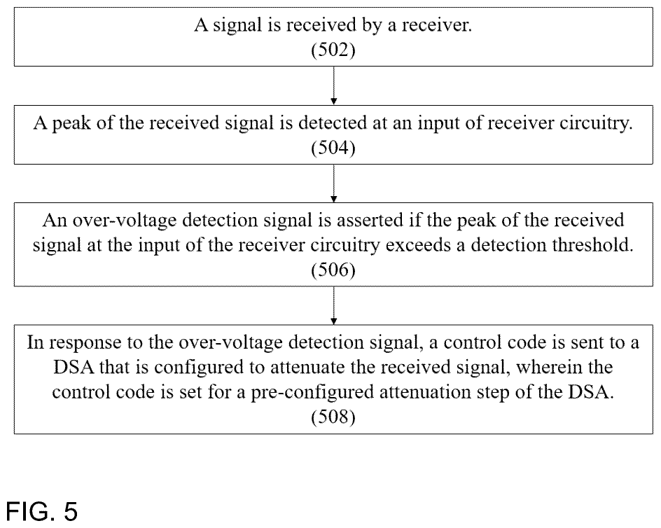

FIG. 5 is a flow diagram of a method for automatic gain control for protecting receiver circuitry from interference signals. A signal is received by a receiver (502). The receiver may be included in a base station transceiver. The received signal may be an RF signal. A peak of the received signal is detected at an input of receiver circuitry (504). An over-voltage detection signal is asserted if the peak of the received signal at the input of the receiver circuitry exceeds a detection threshold (506). In response to the over-voltage detection signal, a control code is sent to a DSA that is configured to attenuate the received signal, wherein the control code is set for a pre-configured attenuation step of the DSA (508).

Automatic gain control (AGC) may be performed to control the attenuation step of the DSA based on a level of the received signal at an output of the receiver circuitry. The pre-configured attenuation step may be maintained until a DSA step setting requested by the AGC exceeds the pre-configured attenuation step. An over-threshold signal which is sent to AGC may be activated on a condition that the over-voltage detection signal is activated. The over-threshold signal may be maintained until a DSA step setting requested by the AGC exceeds the pre-configured attenuation step. A pre-configured DSA step may be used by the AGC while the over-threshold signal is being asserted.

The pre-configured attenuation step may be set to a level that can protect the receiver circuitry from the interference signals. The detection threshold may be set several dB lower than a maximum allowable signal power that can cause damage to the receiver circuitry. The pre-configured attenuation step may be selected to assure that the receiver circuitry operates without damage for any signal level up to a maximum specified level for the receiver circuitry.

Further aspects of the method are described above with respect to the apparatus with reference to FIGS. 1-5.

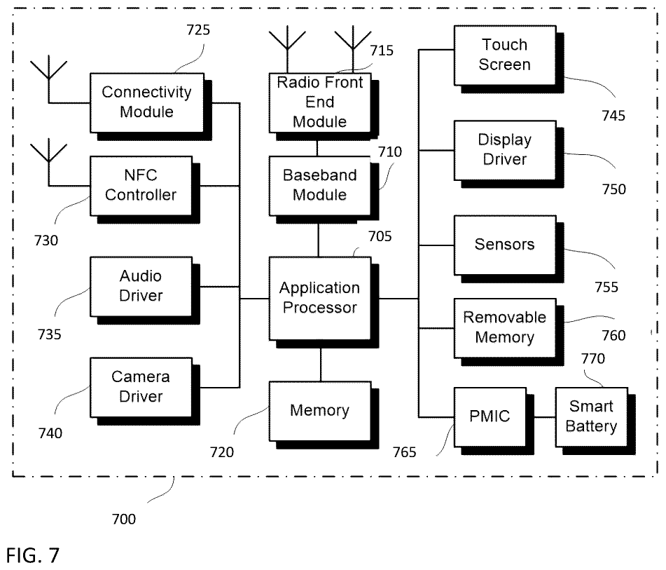

FIG. 7 illustrates a user device 700 in which the examples disclosed herein may be implemented. For example, the examples disclosed herein may be implemented in the radio front-end module 715, in the baseband module 710, etc. The user device 700 may be a mobile device in some aspects and includes an application processor 705, baseband processor 710 (also referred to as a baseband module), radio front end module (RFEM) 715, memory 720, connectivity module 725, near field communication (NFC) controller 730, audio driver 735, camera driver 740, touch screen 745, display driver 750, sensors 755, removable memory 760, power management integrated circuit (PMIC) 765 and smart battery 770.

In some aspects, application processor 705 may include, for example, one or more CPU cores and one or more of cache memory, low drop-out voltage regulators (LDOs), interrupt controllers, serial interfaces such as serial peripheral interface (SPI), inter-integrated circuit (I2C) or universal programmable serial interface module, real time clock (RTC), timer-counters including interval and watchdog timers, general purpose input-output (IO), memory card controllers such as secure digital/multi-media card (SD/MMC) or similar, universal serial bus (USB) interfaces, mobile industry processor interface (MIPI) interfaces and Joint Test Access Group (JTAG) test access ports.

In some aspects, baseband module 710 may be implemented, for example, as a solder-down substrate including one or more integrated circuits, a single packaged integrated circuit soldered to a main circuit board, and/or a multi-chip module containing two or more integrated circuits.

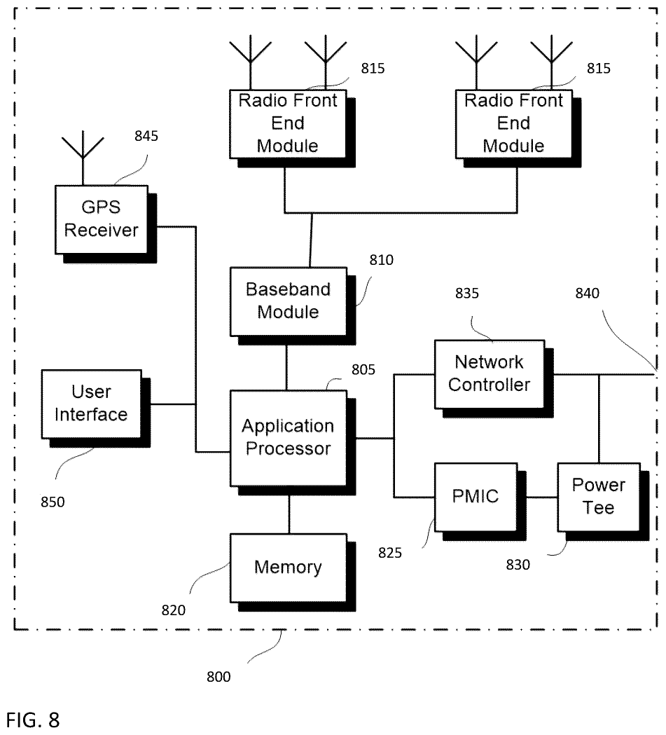

FIG. 8 illustrates a base station or infrastructure equipment radio head 800 in which the examples disclosed herein may be implemented. For example, the examples disclosed herein may be implemented in the radio front-end module 815, in the baseband module 810, etc. The base station radio head 800 may include one or more of application processor 805, baseband modules 810, one or more radio front end modules 815, memory 820, power management circuitry 825, power tee circuitry 830, network controller 835, network interface connector 840, satellite navigation receiver module 845, and user interface 850.

In some aspects, application processor 805 may include one or more CPU cores and one or more of cache memory, low drop-out voltage regulators (LDOs), interrupt controllers, serial interfaces such as SPI, I2C or universal programmable serial interface module, real time clock (RTC), timer-counters including interval and watchdog timers, general purpose IO, memory card controllers such as SD/MMC or similar, USB interfaces, MIPI interfaces and Joint Test Access Group (JTAG) test access ports.

In some aspects, baseband processor 810 may be implemented, for example, as a solder-down substrate including one or more integrated circuits, a single packaged integrated circuit soldered to a main circuit board or a multi-chip module containing two or more integrated circuits.

In some aspects, memory 820 may include one or more of volatile memory including dynamic random access memory (DRAM) and/or synchronous dynamic random access memory (SDRAM), and nonvolatile memory (NVM) including high-speed electrically erasable memory (commonly referred to as Flash memory), phase change random access memory (PRAM), magneto resistive random access memory (MRAM) and/or a three-dimensional crosspoint memory. Memory 820 may be implemented as one or more of solder down packaged integrated circuits, socketed memory modules and plug-in memory cards.

In some aspects, power management integrated circuitry 825 may include one or more of voltage regulators, surge protectors, power alarm detection circuitry and one or more backup power sources such as a battery or capacitor. Power alarm detection circuitry may detect one or more of brown out (under-voltage) and surge (over-voltage) conditions.

In some aspects, power tee circuitry 830 may provide for electrical power drawn from a network cable to provide both power supply and data connectivity to the base station radio head 800 using a single cable.

In some aspects, network controller 835 may provide connectivity to a network using a standard network interface protocol such as Ethernet. Network connectivity may be provided using a physical connection which is one of electrical (commonly referred to as copper interconnect), optical or wireless.

In some aspects, satellite navigation receiver module 845 may include circuitry to receive and decode signals transmitted by one or more navigation satellite constellations such as the global positioning system (GPS), Globalnaya Navigatsionnaya Sputnikovaya Sistema (GLONASS), Galileo and/or BeiDou. The receiver 845 may provide data to application processor 805 which may include one or more of position data or time data. Application processor 805 may use time data to synchronize operations with other radio base stations.

In some aspects, user interface 850 may include one or more of physical or virtual buttons, such as a reset button, one or more indicators such as light emitting diodes (LEDs) and a display screen.

Another example is a computer program having a program code for performing at least one of the methods described herein, when the computer program is executed on a computer, a processor, or a programmable hardware component. Another example is a machine-readable storage including machine readable instructions, when executed, to implement a method or realize an apparatus as described herein. A further example is a machine-readable medium including code, when executed, to cause a machine to perform any of the methods described herein.

The examples as described herein may be summarized as follows:

An example (e.g., example 1) relates to an apparatus for protecting receiver circuitry from interference signals. The apparatus may include a DSA configured to attenuate a received signal, an over-voltage detector configured to detect a peak of the received signal at an input of receiver circuitry, and activate an over-voltage detection signal if the peak of the received signal exceeds a detection threshold, and a digital control block configured to send a control code to the DSA to control an attenuation step of the DSA. The digital control block is configured to send a control code to set the attenuation step of the DSA at a pre-configured attenuation step in response to the over-voltage detection signal asserted by the over-voltage detector.

Another example, (e.g., example 2) relates to a previously described example (e.g., example 1), wherein the apparatus may further include an AGC controller configured to send a DSA step setting to the digital control block to control the attenuation step of the DSA based on a level of the received signal at an output of the receiver circuitry.

Another example, (e.g., example 3) relates to a previously described example (e.g., example 2), wherein the digital control block is configured to maintain the pre-configured attenuation step until a DSA step setting requested by the AGC controller exceeds the pre-configured attenuation step.

Another example, (e.g., example 4) relates to a previously described example (e.g., example 3), wherein the digital control block is configured to activate an over-threshold signal to the AGC controller if the over-voltage detection signal is activated and maintain the over-threshold signal until the DSA step setting requested by the AGC controller exceeds the pre-configured attenuation step.

Another example, (e.g., example 5) relates to a previously described example (e.g., example 4), wherein the AGC controller is configured to use a pre-configured step for AGC control while the over-threshold signal is being asserted.

Another example, (e.g., example 6) relates to a previously described example (e.g., any one of examples 1-5), wherein the receiver circuitry includes a LNA, and the over-voltage detector is configured to detect the peak of the received signal at an input of the LNA.

Another example, (e.g., example 7) relates to a previously described example (e.g., any one of examples 1-6), wherein the pre-configured attenuation step of the DSA is set to a level that can protect the receiver circuitry from the interference signals.

Another example, (e.g., example 8) relates to a previously described example (e.g., any one of examples 1-7), wherein the detection threshold is set several dB lower than a maximum allowable signal power that can cause damage to the receiver circuitry.

Another example, (e.g., example 9) relates to a previously described example (e.g., any one of examples 1-8), wherein the pre-configured attenuation step is selected to assure that the receiver circuitry operates without damage for any signal level up to a maximum specified level for the receiver circuitry.

Another example, (e.g., example 10) relates to a previously described example (e.g., any one of examples 1-9), wherein the received signal is an RF signal.

Another example, (e.g., example 11) relates to a base station transceiver chip including the apparatus of claim 1.

Another example, (e.g., example 12) relates to a method for automatic gain control for protecting receiver circuitry from interference signals. The method may include receiving a signal, detecting a peak of the received signal at an input of receiver circuitry, activating an over-voltage detection signal if the peak of the received signal at the input of the receiver circuitry exceeds a detection threshold, and sending a control code to a DSA that is configured to attenuate the received signal. The control code is set for a pre-configured attenuation step of the DSA in response to the over-voltage detection signal.

Another example, (e.g., example 13) relates to a previously described example (e.g., example 12), the method may further include performing AGC to control the attenuation step of the DSA based on a level of the received signal at an output of the receiver circuitry.

Another example, (e.g., example 14) relates to a previously described example (e.g., example 13), wherein the pre-configured attenuation step is maintained until a DSA step setting requested by the AGC exceeds the pre-configured attenuation step.

Another example, (e.g., example 15) relates to a previously described example (e.g., example 14), further comprising activating an over-threshold signal which is sent to AGC on a condition that the over-voltage detection signal is activated, wherein the over-threshold signal is maintained until a DSA step setting requested by the AGC exceeds the pre-configured attenuation step.

Another example, (e.g., example 16) relates to a previously described example (e.g., example 15), wherein a pre-configured step is used by the AGC while the over-threshold signal is being asserted.

Another example, (e.g., example 17) relates to a previously described example (e.g., any one of examples 12-16), wherein the pre-configured attenuation step is set to a level that can protect the receiver circuitry from the interference signals.

Another example, (e.g., example 18) relates to a previously described example (e.g., any one of examples 12-17), wherein the detection threshold is set several dB lower than a maximum allowable signal power that can cause damage to the receiver circuitry.

Another example, (e.g., example 19) relates to a previously described example (e.g., any one of examples 12-18), wherein the pre-configured attenuation step is selected to assure that the receiver circuitry operates without damage for any signal level up to a maximum specified level for the receiver circuitry.

Another example, (e.g., example 20) relates to a previously described example (e.g., any one of examples 12-19), wherein the received signal is an RF signal.

The aspects and features mentioned and described together with one or more of the previously detailed examples and figures, may as well be combined with one or more of the other examples in order to replace a like feature of the other example or in order to additionally introduce the feature to the other example.

Examples may further be or relate to a computer program having a program code for performing one or more of the above methods, when the computer program is executed on a computer or processor. Steps, operations or processes of various above-described methods may be performed by programmed computers or processors. Examples may also cover program storage devices such as digital data storage media, which are machine, processor or computer readable and encode machine-executable, processor-executable or computer-executable programs of instructions. The instructions perform or cause performing some or all of the acts of the above-described methods. The program storage devices may comprise or be, for instance, digital memories, magnetic storage media such as magnetic disks and magnetic tapes, hard drives, or optically readable digital data storage media. Further examples may also cover computers, processors or control units programmed to perform the acts of the above-described methods or (field) programmable logic arrays ((F) PLAs) or (field) programmable gate arrays ((F) PGAs), programmed to perform the acts of the above-described methods.

The description and drawings merely illustrate the principles of the disclosure. Furthermore, all examples recited herein are principally intended expressly to be only for pedagogical purposes to aid the reader in understanding the principles of the disclosure and the concepts contributed by the inventor(s) to furthering the art. All statements herein reciting principles, aspects, and examples of the disclosure, as well as specific examples thereof, are intended to encompass equivalents thereof.

A functional block denoted as “means for . . . ” performing a certain function may refer to a circuit that is configured to perform a certain function. Hence, a “means for s.th.” may be implemented as a “means configured to or suited for s.th.”, such as a device or a circuit configured to or suited for the respective task.

Functions of various elements shown in the figures, including any functional blocks labeled as “means”, “means for providing a sensor signal”, “means for generating a transmit signal.”, etc., may be implemented in the form of dedicated hardware, such as “a signal provider”, “a signal processing unit”, “a processor”, “a controller”, etc. as well as hardware capable of executing software in association with appropriate software. When provided by a processor, the functions may be provided by a single dedicated processor, by a single shared processor, or by a plurality of individual processors, some of which or all of which may be shared. However, the term “processor” or “controller” is by far not limited to hardware exclusively capable of executing software but may include digital signal processor (DSP) hardware, network processor, application specific integrated circuit (ASIC), field programmable gate array (FPGA), read only memory (ROM) for storing software, random access memory (RAM), and non-volatile storage. Other hardware, conventional and/or custom, may also be included.

A block diagram may, for instance, illustrate a high-level circuit diagram implementing the principles of the disclosure. Similarly, a flow chart, a flow diagram, a state transition diagram, a pseudo code, and the like may represent various processes, operations or steps, which may, for instance, be substantially represented in computer readable medium and so executed by a computer or processor, whether or not such computer or processor is explicitly shown. Methods disclosed in the specification or in the claims may be implemented by a device having means for performing each of the respective acts of these methods.

It is to be understood that the disclosure of multiple acts, processes, operations, steps or functions disclosed in the specification or claims may not be construed as to be within the specific order, unless explicitly or implicitly stated otherwise, for instance for technical reasons. Therefore, the disclosure of multiple acts or functions will not limit these to a particular order unless such acts or functions are not interchangeable for technical reasons. Furthermore, in some examples a single act, function, process, operation or step may include or may be broken into multiple sub-acts, -functions, -processes, -operations or -steps, respectively. Such sub acts may be included and part of the disclosure of this single act unless explicitly excluded.

Furthermore, the following claims are hereby incorporated into the detailed description, where each claim may stand on its own as a separate example. While each claim may stand on its own as a separate example, it is to be noted that—although a dependent claim may refer in the claims to a specific combination with one or more other claims—other examples may also include a combination of the dependent claim with the subject matter of each other dependent or independent claim. Such combinations are explicitly proposed herein unless it is stated that a specific combination is not intended. Furthermore, it is intended to include also features of a claim to any other independent claim even if this claim is not directly made dependent to the independent claim.

1. An apparatus for protecting receiver circuitry from interference signals, comprising:
a digital step attenuator (DSA) configured to attenuate a received signal;
an over-voltage detector configured to detect a peak of the received signal at an input of receiver circuitry, and activate an over-voltage detection signal if the peak of the received signal exceeds a detection threshold; and
a digital control block configured to send a control code to the DSA to control an attenuation step of the DSA,
wherein the digital control block is configured to send a control code to set the attenuation step of the DSA at a pre-configured attenuation step in response to the over-voltage detection signal asserted by the over-voltage detector.

2. The apparatus of claim 1 further comprising:
an automatic gain control (AGC) controller configured to send a DSA step setting to the digital control block to control the attenuation step of the DSA based on a level of the received signal at an output of the receiver circuitry.

3. The apparatus of claim 2, wherein the digital control block is configured to maintain the pre-configured attenuation step until a DSA step setting requested by the AGC controller exceeds the pre-configured attenuation step.

4. The apparatus of claim 3, wherein the digital control block is configured to activate an over-threshold signal to the AGC controller if the over-voltage detection signal is activated and maintain the over-threshold signal until the DSA step setting requested by the AGC controller exceeds the pre-configured attenuation step.

5. The apparatus of claim 4, wherein the AGC controller is configured to use a pre-configured step for AGC control while the over-threshold signal is being asserted.

6. The apparatus of claim 1, wherein the receiver circuitry includes a low noise amplifier (LNA), and the over-voltage detector is configured to detect the peak of the received signal at an input of the LNA.

7. The apparatus of claim 1, wherein the pre-configured attenuation step of the DSA is set to a level that can protect the receiver circuitry from the interference signals.

8. The apparatus of claim 1, wherein the detection threshold is set several dB lower than a maximum allowable signal power that can cause damage to the receiver circuitry.

9. The apparatus of claim 1, wherein the pre-configured attenuation step is selected to assure that the receiver circuitry operates without damage for any signal level up to a maximum specified level for the receiver circuitry.

10. The apparatus of claim 1, wherein the received signal is a radio frequency (RF) signal.

11. A base station transceiver chip including the apparatus of claim 1.

12. A method for automatic gain control for protecting receiver circuitry from interference signals, comprising:
receiving a signal;
detecting a peak of the received signal at an input of receiver circuitry;
activating an over-voltage detection signal if the peak of the received signal at the input of the receiver circuitry exceeds a detection threshold; and
sending a control code to a digital step attenuator (DSA) that is configured to attenuate the received signal, wherein the control code is set for a pre-configured attenuation step of the DSA in response to the over-voltage detection signal.

13. The method of claim 12, further comprising:
performing automatic gain control (AGC) to control the attenuation step of the DSA based on a level of the received signal at an output of the receiver circuitry.

14. The method of claim 13, wherein the pre-configured attenuation step is maintained until a DSA step setting requested by the AGC exceeds the pre-configured attenuation step.

15. The method of claim 14, further comprising:
activating an over-threshold signal which is sent to AGC on a condition that the over-voltage detection signal is activated, wherein the over-threshold signal is maintained until a DSA step setting requested by the AGC exceeds the pre-configured attenuation step.

16. The method of claim 15, wherein a pre-configured step is used by the AGC while the over-threshold signal is being asserted.

17. The method of claim 12, wherein the pre-configured attenuation step is set to a level that can protect the receiver circuitry from the interference signals.

18. The method of claim 12, wherein the detection threshold is set several dB lower than a maximum allowable signal power that can cause damage to the receiver circuitry.

19. The method of claim 12, wherein the pre-configured attenuation step is selected to assure that the receiver circuitry operates without damage for any signal level up to a maximum specified level for the receiver circuitry.

20. The method of claim 12, wherein the received signal is a radio frequency (RF) signal.
